(19) United States
(12) Patent Application Publication
(10) Pub. No.: US 2025/0286349 A1
(43) Pub. Date: Sep. 11, 2025

(54) VERTICAL-CAVITY SURFACE-EMITTING LASER WITH INTEGRATED MULTI-LAYER META-SURFACE WITH SUPPRESSED BACK REFLECTIONS

(71) Applicant: Lumentum Operations LLC, San Jose, CA (US)

(72) Inventors: Richa DUBEY, Milpitas, CA (US); Vincent V. WONG, Los Altos, CA (US); Matthew Glenn PETERS, Menlo Park, CA (US); Michael MILLER, Ottawa (CA); Stephen BAGNALD, Ottawa (CA)

(21) Appl. No.: 18/990,209

(22) Filed: Dec. 20, 2024

Related U.S. Application Data
(60) Provisional application No. 63/563,777, filed on Mar. 11, 2024.

(51) Int. Cl. H01S 5/183

(52) U.S. Cl. CPC H01S 5/18386

(57) ABSTRACT

In some implementations, an optical device may comprise a base layer and an antireflective diffractive optical element (DOE) comprising an array of meta-atom unit cells on the base layer. In some implementations, the meta-atom unit cells may each comprise a first set of layers formed from one or more high index dielectric materials, wherein the first set of layers includes a meta-atom layer, and a second set of layers formed from one or more low index dielectric materials. In some implementations, the first set of layers and the second set of layers may be arranged in an identical sequence in each of the meta-atom unit cells. In some implementations, the antireflective DOE may be integrated with a vertical-cavity surface-emitting laser (VCSEL) to suppress back reflections of a laser beam emitted by the VCSEL.

### CROSS-REFERENCE TO RELATED APPLICATION

This Patent application claims priority to U.S. Provisional Patent Application No. 63/563,777, filed on Mar. 11, 2024, and entitled “VERTICAL-CAVITY SURFACE-EMITTING LASER WITH INTEGRATED MULTI-LAYER META-LENS FOR SUPPRESSING BACK REFLECTIONS.” The disclosure of the prior Application is considered part of and is incorporated by reference into this Patent Application.

### TECHNICAL FIELD

The present disclosure relates generally to a diffractive optical element (DOE) and to a DOE that includes an array of meta-atom unit cells with antireflective properties.

### BACKGROUND

A diffractive optical element (DOE) may be used to direct a beam. For example, a DOE, such as a diffractive lens, a spot array illuminator, a spot array generator, a beam splitter, and/or a Fourier array generator, among other examples, may be used to split a beam, shape a beam, focus a beam, or the like. In some examples, a DOE may be incorporated into an optical device, such as a multicast switch, a wavelength selective switch, a gesture recognition system, or a motion sensing system. In some other examples, a DOE may be incorporated into a vertical-emitting device, such as a vertical-cavity surface-emitting laser (VCSEL). For example, a VCSEL may emit a laser beam in a direction perpendicular to a surface of a substrate (e.g., vertically from a surface of a semiconductor wafer). In contrast to edge-emitting devices, vertical-emitting devices may allow for testing to occur at intermediate steps of wafer fabrication.

### SUMMARY

In some implementations, an optical system includes a VCSEL comprising a top surface, wherein the VCSEL is configured to emit a laser beam in a direction perpendicular to the top surface; a base layer on the top surface of the VCSEL; and an antireflective DOE on the base layer, wherein the antireflective DOE comprises an array of meta-atom unit cells that each include one or more high index dielectric layers and one or more low index dielectric layers arranged in an identical sequence.

In some implementations, a method for fabricating an optical system includes forming a base layer; and forming an antireflective DOE comprising an array of meta-atom unit cells on the base layer, wherein the meta-atom unit cells each comprise: a first set of layers formed from one or more high index dielectric materials, wherein the first set of layers includes a meta-atom layer; and a second set of layers formed from one or more low index dielectric materials, wherein the first set of layers and the second set of layers are arranged in an identical sequence in each of the meta-atom unit cells.

In some implementations, a method for operating an optical system includes emitting, by a VCSEL comprising a top surface, a laser beam in a direction perpendicular to the top surface of the VCSEL; and diffracting the laser beam by an antireflective diffractive coating on the top surface of the VCSEL, wherein the antireflective diffractive coating comprises an array of meta-atom unit cells formed on the top surface of the VCSEL, and wherein the meta-atom unit cells each comprise: a first set of layers formed from one or more high index dielectric materials, wherein the first set of layers includes a meta-atom layer; and a second set of layers formed from one or more low index dielectric materials.

In some implementations, an optical system includes a substrate; and a DOE on the substrate, wherein the DOE comprises an array of meta-atom unit cells that each include one or more high index dielectric layers and one or more low index dielectric layers that have respective thicknesses and are arranged in an identical sequence such that the one or more high index dielectric layers and the one or more low index dielectric layers collectively provide the DOE with an antireflective property . . .

### BRIEF DESCRIPTION OF THE DRAWINGS

FIG. 1 is a diagram illustrating an example of spot array generation using a DOE and a converging lens.

FIG. 2 is a diagram illustrating example characteristics related to a set of DOEs.

FIGS. 3A-3G are diagrams example implementations of DOEs.

FIG. 4 is a diagram illustrating an example VCSEL.

FIG. 5A is a diagram illustrating an example of a VCSEL with an integrated DOE having antireflective properties.

FIG. 5B is a diagram illustrating an example structure associated with an antireflective DOE.

FIG. 6 is a diagram illustrating example performance characteristics associated with an antireflective DOE.

FIG. 7 is a diagram illustrating an example method for fabricating an optical system that includes an antireflective DOE.

FIG. 8 is a diagram illustrating an example method for operating an optical system that includes an antireflective DOE.

### DETAILED DESCRIPTION

The following detailed description of example implementations refers to the accompanying drawings. The same reference numbers in different drawings may identify the same or similar elements.

A vertical-emitting device, such as a VCSEL, is a laser in which a laser beam is emitted in a direction vertical to a surface of a substrate (e.g., perpendicularly relative to a surface of a semiconductor wafer). In contrast to edge-emitting devices, vertical-emitting devices may allow for testing to occur at intermediate steps of wafer fabrication. In some cases, multiple vertical-emitting devices may be arranged to form an array. For example, multiple vertical-emitting devices (herein referred to as emitters) may be arranged to form a VCSEL array, such as a grid VCSEL array (e.g., where multiple emitters are uniformly spaced and oxidation trenches may be shared by two or more emitters) or a non-grid VCSEL array (e.g., where multiple emitters are not uniformly spaced and each emitter is associated with a set of oxidation trenches that may or may not be shared).

Because VCSELs have low power consumption, high efficiency, compact size, and can be manufactured in arrays, VCSELs are used in various applications, such as short-range optical communication systems, facial recognition and gesture detection in consumer electronics, time-of-flight (ToF) or structured light cameras, and/or light detection and ranging (LiDAR), among other examples. For example, VCSELs may be used to provide infrared light used to illuminate a scene for ToF cameras, may project infrared light onto an eye to track eye movements in eye-tracking and extended reality (XR) headsets, and/or may emit pulses of infrared light that reflects off objects to precisely map a three-dimensional environment in a LiDAR system. Accordingly, for many VCSEL applications, a high-quality beam with a narrow beam divergence may be desired. In some cases, techniques to improve beam quality and/or reduce beam divergence in a VCSEL may include small confinement apertures and mode filters, which have been shown to eliminate higher order modes and reduce the divergence. However, these techniques introduce losses to lasing modes, dominantly to higher order modes, and therefore impose penalties on VCSEL performance. Accordingly, achieving high output power in VCSEL applications poses various challenges. For example, when an optical component is integrated with a top-emitting VCSEL (e.g., to improve beam quality or reduce beam divergence), the optical component causes light to couple back into the VCSEL cavity, and the back reflections can perturb VCSEL characteristics such as a lasing wavelength and threshold.

Some implementations described herein relate to an antireflective diffractive optical element (DOE) that may be integrated with a VCSEL to minimize or suppress back reflections or to otherwise mitigate the effect that back reflections may have in a VCSEL. For example, in some implementations, the DOE may comprise a multi-layer meta-atom structure, which may be referred to herein as a meta-surface, a meta-lens or the like, composed of an array of meta-atom unit cells. For example, as described herein, the DOE may include a meta-surface with a sub-wavelength feature size and a capability to diffuse a laser beam profile, diffract light, control polarization, focus light, collimate light, or provide other functionalities in a VCSEL. Accordingly, in some implementations, the meta-atom unit cells may comprise nano structures that are etched into a high index material, such as amorphous silicon (a-Si), gallium arsenide (GaAs), silicon nitride (SiNx), or titanium dioxide (TiO₂), among other examples, that has low to moderate losses at an operating wavelength associated with the VCSEL. For example, a base layer may be formed on a top surface of a VCSEL, a layer of high index material may be deposited on the base layer to a specific thickness, and meta-atoms may be etched into the layer of high index material. The meta-atoms may form a layer in a multi-layer meta-atom structure, where the multiple layers are arranged in a specific sequence of high index and low index dielectric materials with carefully designed thicknesses to behave as an antireflective DOE. In this way, relative to a VCSEL without the antireflective DOE, a VCSEL integrated with the antireflective DOE may emit a laser beam that has a lower reflection, a higher transmission, and a lower absorption.

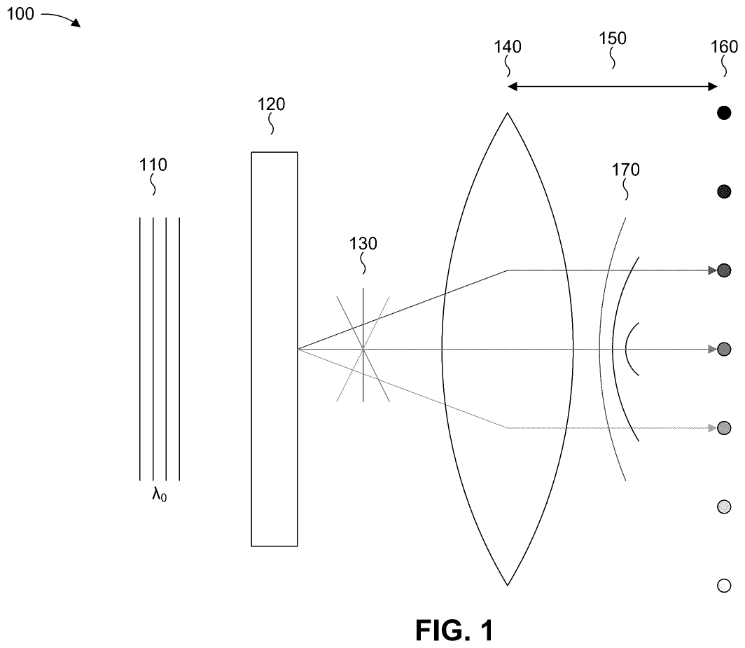

FIG. 1 is a diagram illustrating an example 100 of spot array generation using a DOE and a converging lens as a spot array illuminator (sometimes termed a spot array generator).

As shown in FIG. 1, an incident plane wave 110, with a wavelength of λ₀, is directed toward a DOE 120. In some implementations, the DOE 120 may be a carrier grating with a varying fill factor, as described herein. For example, the DOE 120 may be associated with a set of carrier periods, and each carrier period may include at least one stack and at least one gap. A size of the at least one stack and the at least one gap in each carrier period may correspond to a fill factor, and the fill factor may be configured to control a phase delay between carrier periods.

In some implementations, the DOE 120 may include, for example, alternating (Si) thin layers and silicon dioxide (SiO₂) thin layers, alternating hydrogenated silicon (Si:H) thin layers and SiO₂ thin layers, and/or layers formed from other suitable materials to form the stacks and gaps of the carrier grating. In some implementations, a size of a carrier period may be configured based on the wavelength 20. For example, the DOE 120 may be configured to be a sub-wavelength carrier grating with carrier periods associated with a width of less than the wavelength λ₀. In some implementations, layers of the DOE 120 may be configured to provide an anti-reflective functionality. For example, the DOE 120 may include a single set of index-matched thin layers to provide the anti-reflective functionality and/or multiple sets of index-matched thin film layers to provide the anti-reflective functionality. Additionally, or alternatively, the DOE 120 may include an array of meta-atom unit cells, which may include nano structures such as cylindrical pillars, rectangular or square posts, triangles, and/or holes arranged in a lattice with a rectangular, square, hexagonal, or other suitable shape. Furthermore, each meta-atom unit cell may include multiple layers that are arranged in an identical sequence that includes one or more layers formed from a high index dielectric material and one or more layers formed from a low index dielectric material, with the layers having respective thicknesses that are designed to reduce reflection, increase transmission, and reduce absorption. Additional details regarding the array of meta-atom unit cells that may form the DOE 120 are described herein. In some implementations, a thin layer may be a layer with a thickness of less than a threshold as described herein, such as a thin film layer or the like. In some implementations, the anti-reflective functionality may be provided for a threshold range of fill factors, as described herein.

In some implementations, the incident plane wave 110 may have a wavelength in a range from approximately 700 nanometers (nm) to approximately 2000 nm, approximately 1000 nm to approximately 1800 nm, approximately 1400 nm to approximately 1600 nm, approximately 1500 nm to approximately 1600 nm, approximately 800 nm to 1000 nm, approximately 600 nm to 1000 nm, and/or approximately 850 nm to 950 nm, among other examples. Additionally, or alternatively, the incident plane wave 110 may be associated with a center wavelength of approximately 1550 nm, which may be a wavelength at which the DOE 120 provides a threshold phase delay and/or an anti-reflective functionality. In some implementations, a maximum transmissive phase delay provided by the DOE 120 (e.g., between different carrier periods of the DOE 120) may be greater than or equal to x, 2x, 4x, and/or another suitable value. Additional details regarding the DOE 120 are described herein.

As further shown in FIG. 1, the DOE 120 diffracts incident plane wave 110, and directs wavefront 130 (e.g., diffracted orders of the incident plane wave 110) toward a converging lens 140. The converging lens 140 is separated by a focal distance 150 from a focal plane 160. In some implementations, the DOE 120 may be used in a gesture recognition system, and the focal plane 160 may be a target for gesture recognition. Additionally, or alternatively, the focal plane 160 may be an object (e.g., for a motion sensing system), a communications target (e.g., for an optical communications system), or the like.

As further shown in FIG. 1, based on the converging lens 140 altering an orientation of the wavefront 130 to form wavefront 170, the wavefront 170 is directed toward the focal plane 160 causing a multiple spot array pattern to be formed at the focal plane 160. In some implementations, the DOE 120 may be used to create a one-dimensional spot array. In some implementations, the DOE 120 may be used to create a two-dimensional spot array. In this way, the DOE 120 may be used as a spot array illuminator to create a spot array at the focal plane 160 from the incident plane wave 110, thereby enabling a gesture recognition system, a motion sensing system, an optical communications system, or the like.

As indicated above, FIG. 1 is provided as an example. Other examples may differ from what is described with regard to FIG. 1.

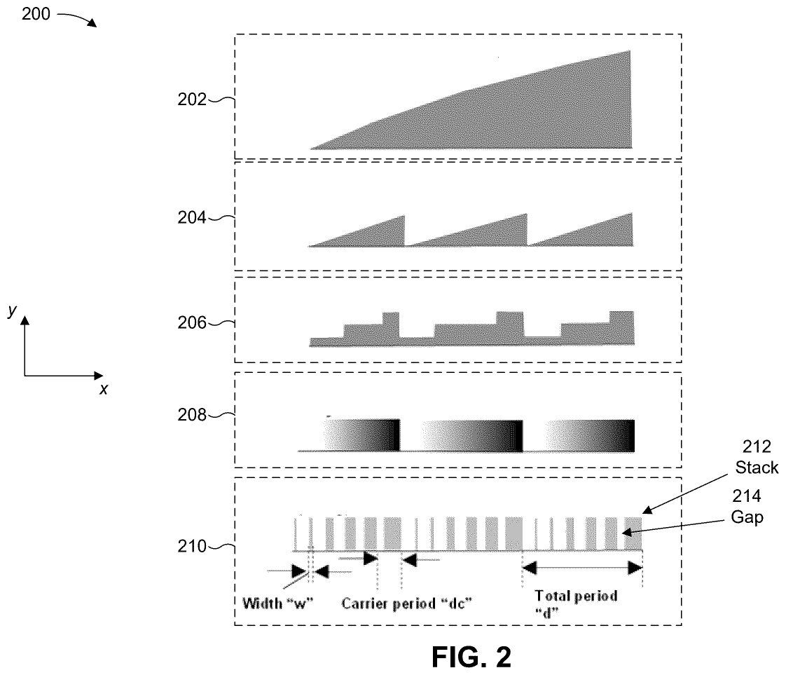

FIG. 2 is a diagram 200 illustrating example characteristics related to a set of DOEs. As shown in FIG. 2, and by reference numbers 202-210, the set of DOEs may be associated with different relief profiles for refractive lenses.

As shown in FIG. 2, and by reference number 202, a first DOE may be associated with a continuous phase relief profile for a refractive optical element (e.g., a lens). The first DOE may provide a continuous experienced phase delay from 0 to a maximum phase delay across a surface of the first DOE. Although described herein as a 0 phase delay, the 0 phase delay may be a minimum phase delay. In other words, the 0 phase delay may be a 0 relative phase delay, and the maximum phase delay may be a maximum relative phase delay (relative to the 0 phase delay). As further shown by reference number 204, a second DOE may be associated with a modulus 2π Fresnel zone continuous phase diffractive optic. The second DOE may provide a periodic continuous phase delay from 0 to a maximum phase delay across a surface of the second DOE. For example, the second DOE may include a first region with an experienced phase delay of 0 to the maximum phase delay, a second region with an experienced phase delay of 0 to the maximum phase delay, and a third region with an experienced phase delay of 0 to the maximum phase delay.

As further shown in FIG. 2, and by reference number 206, a third DOE may be associated with a periodic n-level (e.g., two or more level) relief profile. For example, the third DOE may include a plurality of discrete levels, each associated with a different experienced phase delay from 0 to a maximum phase delay. In this case, the third DOE includes a first region with a first level with a first phase delay of 0, a second level with a second phase delay between 0 and a maximum phase delay, and a third level with a third phase delay of the maximum phase delay. In addition, the third DOE includes a second region with the first level, second level, and third level, and a third region with the first level, second level, and third level. As further shown by reference number 208, a fourth DOE may be associated with a periodic graded index phased array liquid crystal on substrate (LCOS) optical element. For example, the fourth DOE may provide a set of different phase delays in each region of the LCOS optical element.

As further shown in FIG. 2, and by reference number 210, a fifth DOE may be a sub-wavelength periodic binary grating. For example, the fifth DOE may include a binary (two-level) structure with differing fill factors for stacks 212 or gaps 214 of the fifth DOE. Based on using a two-level grating structure for stacks 212 or gaps 214, the fifth DOE may be associated with reduced manufacturing time and/or cost, improved diffractive efficiency, and/or improved transmittance relative to the first DOE, the second DOE, the third DOE, and/or the fourth DOE. In some implementations, a carrier period (also termed a pitch), dc, with regard to an x direction and a y direction, may be less than a wavelength of incident light, and may be termed sub-wavelength. In this case, based on the carrier period being sub-wavelength, a local effective refractive index, n_{eff}, is caused for incident light. In some implementations, the stacks 212 may comprise meta-atom unit cells, which may include nano structures such as cylindrical pillars, rectangular or square posts, triangles, and/or holes, and the stacks 212 may be arranged in a lattice with a rectangular, square, hexagonal, or other suitable shape. Furthermore, as described herein, each stack 212 (or meta-atom unit cell) may include one or more layers formed from a high index dielectric material and one or more layers formed from a low index dielectric material, which may be arranged in a sequence and have respective thicknesses that are designed to reduce reflection, increase transmission, and reduce absorption of incident light.

In some implementations, a value for the local refractive index is varied across a total period, d, of the fifth DOE. For example, based on a variable fill factor across a total period (e.g., a first carrier period, of the total period, having a first fill factor and a second carrier period, of the total period, having a second fill factor), the local effective refractive index may be varied across the total period. A fill factor may represent a ratio of a width, w, of a stack 212 relative to a width of a carrier period in which the stack 212 is located. Similarly, the fill factor may be related to a ratio of a width of a space between a set of stacks 212, which may be termed a gap 214, relative to the width of the carrier period in which the gap 214 is located. Based on varying the fill factor across the total period, the fifth DOE may be associated with a varying local effective refractive index across the total period, and may form a two-level DOE structure, also termed a binary DOE structure, which may be index matched to an environment or to a substrate over a range of fill factors of a carrier period. In some implementations, another type of multi-level DOE structure may be formed using a carrier grating, such as a three-level DOE, a four-level DOE, or another type of n-level DOE (n≥2). In some implementations, a total period of a DOE may be varied with regard to multiple axes (e.g., with regard to an x direction and a y direction). For example, a two dimensionally varying DOE may be used for a diffractive lens or another use case.

As indicated above, FIG. 2 is provided as an example. Other examples may differ from what is described with regard to FIG. 2.

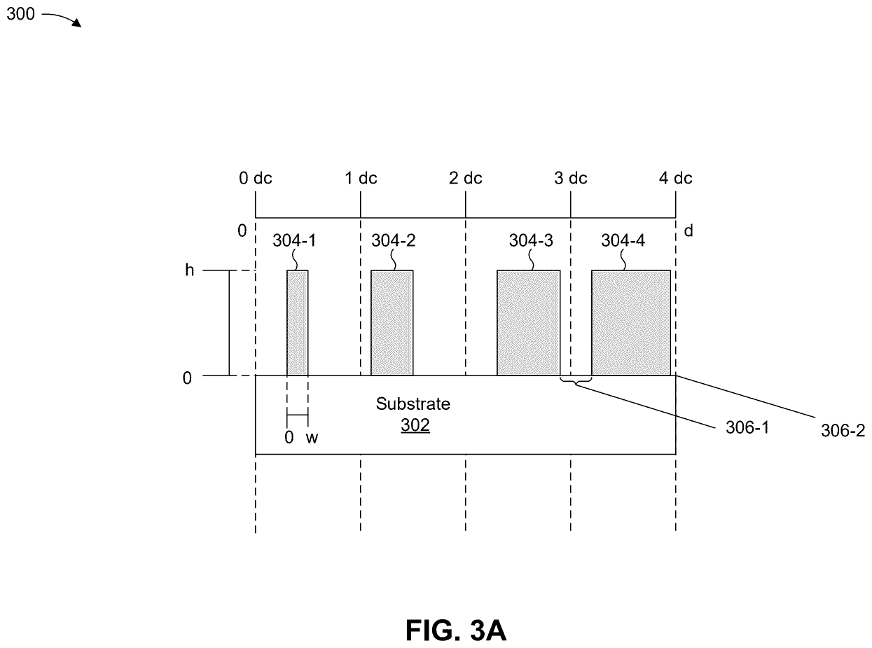

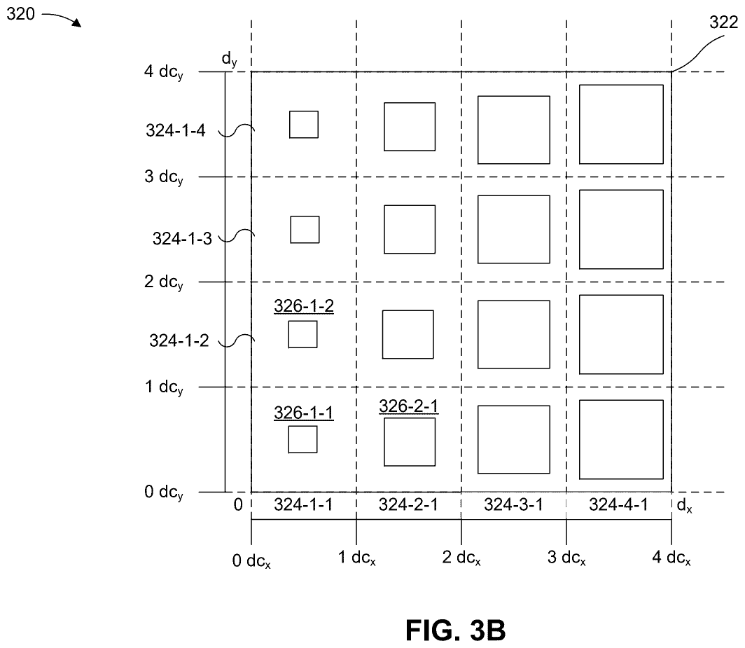

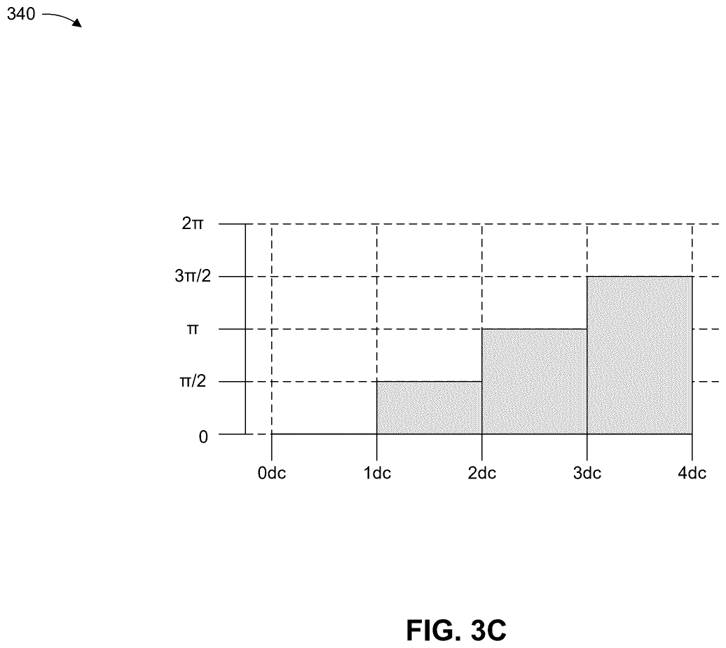

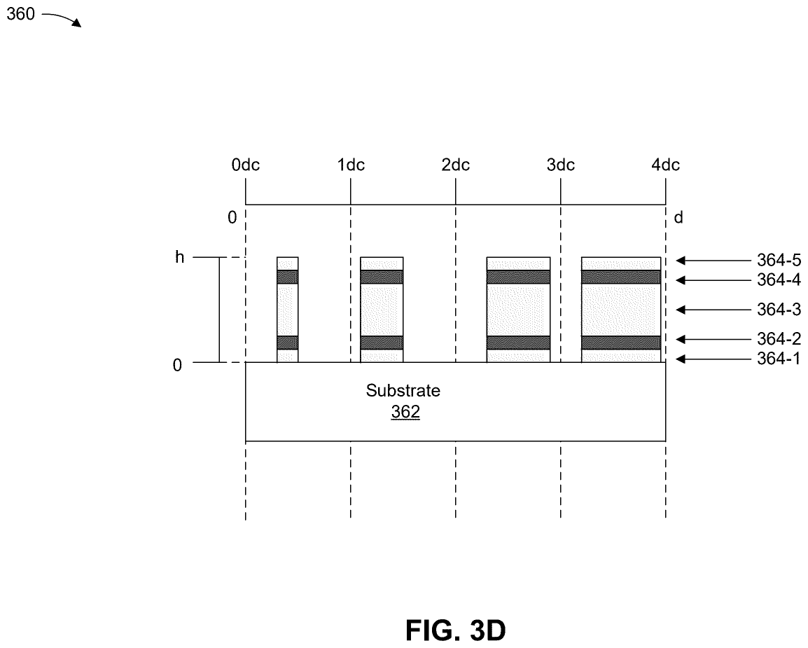

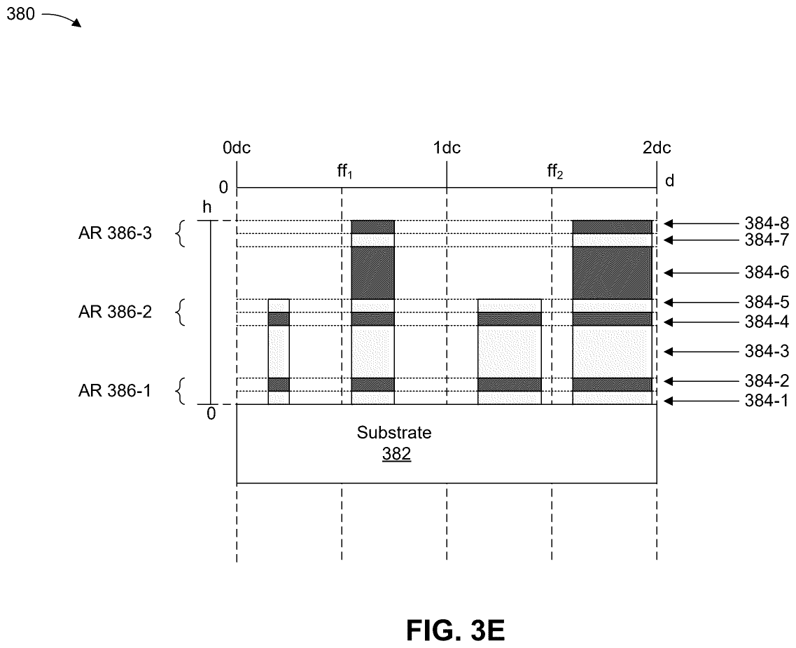

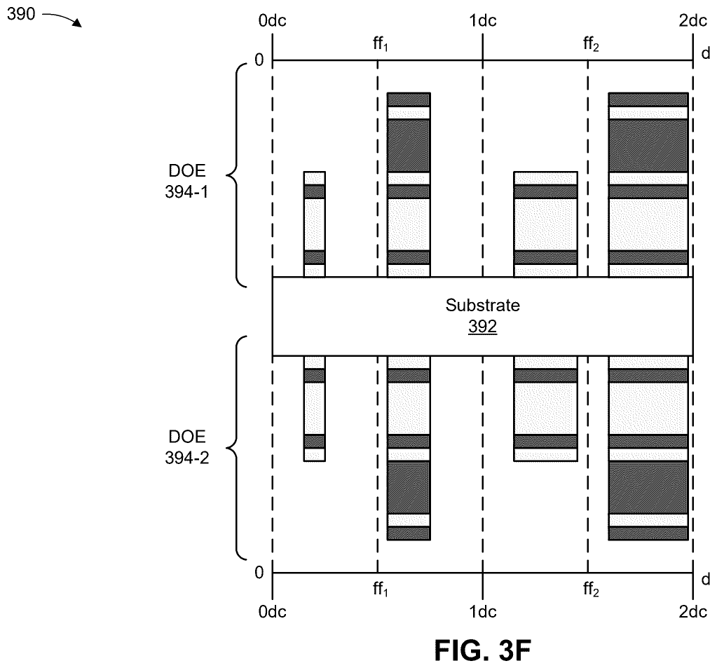

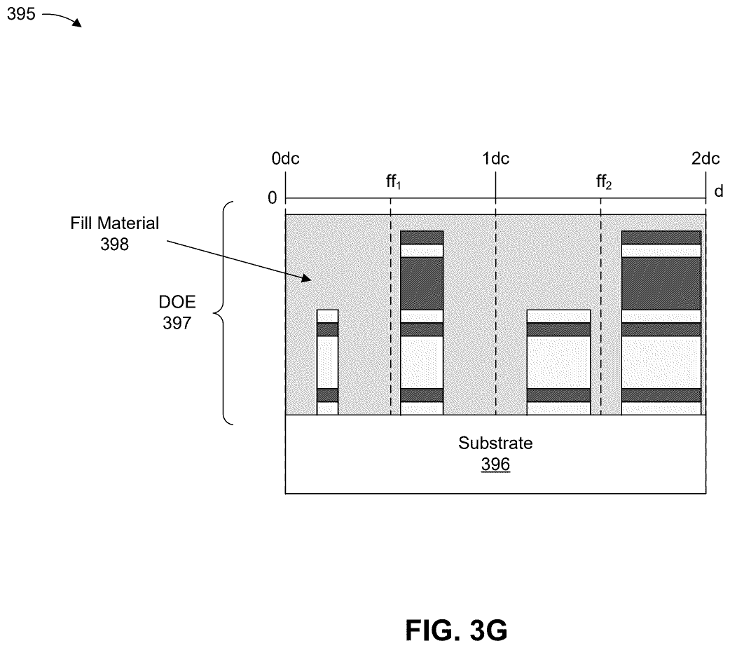

FIGS. 3A-3G are diagrams of example implementations of DOEs. FIG. 3A shows a cross-sectional view of an example DOE 300.

As shown in FIG. 3A, DOE 300 may include a substrate 302. In some implementations, the substrate 302 may be a glass substrate, a fused silica substrate, a borosilicate glass substrate, a crystalline substrate, a polymer substrate or the like. For example, the substrate 302 may be a fused silica substrate with a thickness in a range from approximately 200 micrometers (μm) to approximately 3 millimeters (mm), or of approximately 725 μm, and with a refractive index, n_{sub}, of approximately 1.45. In some implementations, the substrate 302 may be associated with a total period, d, and each period may be defined, with respect to a particular dimension of the substrate 302 by a set of carrier periods, dc. For example, the substrate 302 may include, extending planar with a top surface of the substrate 302, a first carrier period from 0 dc to 1 dc, a second carrier period from 1 dc to 2 dc, a third carrier period from 2 dc to 3 dc, and a fourth carrier period from 3 dc to 4 dc. In some implementations, each carrier period may be associated with at least one stack, and may be a sub-wavelength period. For example, the first carrier period may include stack 304-1, the second carrier period may include stack 304-2, the third carrier period may include stack 304-3, and the fourth carrier period may include stack 304-4. Similarly, each carrier period may be associated with at least one gap. For example, the fourth carrier period may be associated with a portion of gap 306-1 (another portion of gap 306-1 may be included in the third carrier period) and a portion of gap 306-2 (another portion of gap 306-2 may be included in another carrier period of another total period of the DOE 300 on the substrate 302). In this case, the stacks 304 and gaps 306 are castellated in a single dimension planar to a surface of the substrate 302.

In some implementations, each stack 304 may be associated with a particular height, h, above a surface of each gap 306 and/or above a surface of the substrate 302. For example, each stack 304 may be associated with a height in a range from approximately 0.5 μm to approximately 6 μm (e.g., a 4π period at 940 nm using Si and a 2π period at 1550 nm using fused silica), or of approximately 1.2 μm (e.g., a 4π period at 1550 nm using Si). In some implementations, a first stack 304 may be associated with a different height than a second stack 304. For example, stacks 304 of a common carrier period, of different carrier periods, or the like may be associated with different heights above a top surface of substrate 302. Alternatively, in some implementations, each stack may have the same height above the top surface of substrate 302. In some implementations, each gap 306 may be associated with a common depth from a top surface of stacks 304. Additionally, or alternatively, a first gap 306 may be associated with a first depth from a surface of a stack 304 and a second gap 306 may be associated with a second depth from a surface of a stack 304. Collectively, a stack 304 and a gap 306 may form a stack-and-gap structure.

In some implementations, each carrier period may be associated with a fill factor. The fill factor in one dimension and two dimensions, respectively, may be calculated based on equations:

$$ff = w / dc \qquad ( 1 )$$

where ff represents the fill factor, w represents a width of a stack 304 within a particular carrier period in one dimension or an area in two dimensions, and de represents a width of the particular carrier period in one dimension or an area in two dimensions. In some implementations, when a carrier period includes multiple stacks 304, w may represent a sum of widths of the multiple stacks 304 in the carrier period, an average of widths of the multiple stacks 304 in the carrier period, or the like. In some implementations, the fill factor may vary with regard to carrier periods, of a total period, arranged along a dimension planar with a top surface of substrate 302, such that thin anti-reflective layers form stacks 304 and gaps 306 are index matched to an environment or to a substrate over a range of fill factors (e.g., over the first through fourth fill factors as described below). For example, the first carrier period may be associated with a first fill factor, the second carrier period may be associated with a second fill factor, the third carrier period may be associated with a third fill factor, and the fourth carrier period may be associated with a fourth fill factor.

In some implementations, each carrier period of a total period may be associated with a different fill factor. In some implementations, two or more carrier periods of the total period may be associated with a common fill factor and another two or more carrier periods of the total period may be associated with a different fill factor. In some implementations, each carrier period of multiple total periods may be associated with a range of different fill factors. In some implementations, at least one carrier period of a first total period and at least one carrier period of a second total period may be associated with a common fill factor. In some implementations, multiple total periods may be associated with a common average fill factor, a different average fill factor, or the like. In some implementations, each carrier period may be associated with a common fill factor. For example, when the DOE 300 includes carrier periods defined across two dimensions planar with a top surface of the substrate 302 (e.g., and stacks extend in a third dimension perpendicular to the top surface of the substrate 302, as shown), carrier periods linearly arranged with regard to a first of the two dimensions may be associated with a common fill factor and carrier periods linearly arranged with regard to a second of the two dimensions may be associated with different fill factors.

As shown in FIG. 3B, in a top-down view, another example implementation of a DOE 320 may include total periods with carrier periods arranged in two dimensions extending planar with a top surface of a substrate 322. In this case, the stacks and gaps are castellated in two dimensions planar to a surface of the DOE 320. Additionally, or alternatively, the stacks and gaps may be arranged in a lattice structure, such as a rectangular lattice, a square lattice, a hexagonal lattice, or a lattice having another suitable shape.

As further shown in FIG. 3B, the DOE 320 may include, in a first dimension, x, at least one total period, dₓ, and a set of carrier periods dcₓ. Similarly, in a second dimension, y, the DOE 320 may include at least one total period, d_{y}, and a set of carrier periods, dc_{y}. In this way, a carrier grating of the DOE 320 (e.g., stacks and gaps of the DOE 320) may provide a two-dimensional polarization independent DOE. For example, the DOE 320 includes carrier periods 324-1-1, 324-2-1, 324-3-1, and 324-4-1 aligned linearly in the first dimension. Similarly, the DOE 320 includes carrier periods 324-1-1, 324-1-2, 324-1-3, and 324-1-4 aligned linearly in the second dimension. In this case, carrier periods aligned in the second dimension are each associated with a common fill factor, and carrier periods aligned in the first dimension are each associated with a different fill factor. For example, stacks 326-1-1 and 326-1-2 are associated with a common width, resulting in a common fill factor, and stacks 326-1-1 and 326-2-1 are associated with different widths, resulting in a range of different fill factors. In some implementations, a pattern or arrangement of stacks and gaps in the carrier period may be selected based on a particular design technique. For example, a two-dimensional rigorous grating theory technique, a thin film theory technique, a simulated annealing and steepest descent technique, or the like may be used to identify a pattern or arrangement of gaps and stacks to provide a particular phase delay at a particular wavelength for which stacks and gaps provide an anti-reflection functionality.

As shown in FIG. 3C, and by diagram 340, an example phase profile of phase delays is provided for carrier periods of a DOE described herein, such as for the DOE 300 and/or for the DOE 320 with respect to the first (x) dimension. For example, for the first carrier period, a (relative) phase delay of 0 is caused by at least one stack and/or at least one gap of the first carrier period. Similarly, for the second carrier period, a phase delay of π/2 is caused; for the third carrier period, a phase delay of π is caused; and for the fourth carrier period, a phase delay of 3π/2 is caused.

In some implementations, the phase delay of a DOE described herein may be configured for a particular spectral range. For example, the phase delay may be configured for a spectral range at which the stacks and gaps provide an anti-reflective functionality, such as a spectral range with a center illumination wavelength of 1550 nm. In this case, a width of a grating formed by the stacks and gaps may be less than 1550 nm.

Although described herein in terms of a particular set of phase delays, other phase delays are possible, such as other equally spaced phase delays (e.g., 0, π/4, π/2, 3π/4, π), other non-equally spaced phase delays (e.g., 0, π, 3π/2, 7π/8), a combination of equally spaced phase delays and non-equally spaced phase delays, or the like.

As shown in FIG. 3D, another example implementation of a DOE 360 may include multiple thin layers (e.g., thin film layers). For example, stacks of the DOE 360 may be manufactured from multiple layers of thin films on a surface of a substrate 362. In this case, a stack may include a first layer 364-1 of Si, a second layer 364-2 of SiO₂, a third layer 364-3 of Si, a fourth layer 364-4 of SiO₂, and a fifth layer 364-5 of Si. In some implementations, layers 364-1 and 364-2 may form an index-matched pair. Similarly, layers 364-4 and 364-5 may form an index-matched pair. In contrast, layer 364-3 may be a spacer between the index-matched pairs that may be selected to control an effective index of the DOE 360.

In some implementations, layers 364 may be index-matched to the substrate 362, an air interface with layers 364, or the like. In this way, transmittance may be improved relative to other techniques for forming a DOE. Moreover, based on a refractive index of the DOE 360 varying based on a fill factor of carrier periods of the DOE 360, the DOE 360 may be index-matched with reduced manufacturing difficulty relative to index matching based only on material selection. In some implementations, layers 364 may be deposited using a deposition technique. For example, layers 364 may be deposited using thin film deposition (e.g., sputter deposition or the like). In some implementations, stacks may be formed from layers 364 using a masking and etching technique.

In some implementations, layers 364-1 through 364-5 may be associated with a set of thicknesses. For example, the DOE 360 may be associated with a thickness of 53 nm for layer 364-1, 64 nm for layer 364-2, 1000 nm for layer 364-3, 121 nm for layer 364-4, and 28 nm for layer 364-5. In this case, layer 364-3, which may be a spacer layer between the index-matched pairs, provides a phase delay that may be tuned by adjusting the fill factor of stacks and gaps formed using layers 364. In some implementations, layer 364-3 may be associated with a refractive index satisfying a threshold, such as a refractive index greater than 2.0, a refractive index of approximately 3.5, or the like. In some implementations, a spacer layer between index-matched pairs, such as layer 364-3, may be omitted. For example, one or more index-matched pairs of thin film layers may be formed on substrate 362 consecutively and etched to form stacks without a spacer layer, such as layer 364-3.

Alternatively, in some implementations, layers 364-1 through 364-5 may be designed to cooperatively provide low reflections at both interfaces (e.g., at an interface between the substrate 362 and layer 364-1, and at an interface above layer 364-5) and the phase delay function. For example, the refractive index and thickness of each of layers 364-1, 364-2, 364-3, 364-4, and 364-5 may be chosen to work in cooperation with the other layers to provide lower reflection, higher transmission, and/or lower absorption. In some implementations, a pattern or arrangement of stacks and gaps in the carrier period in combination with the refractive index and thickness of each layer may be selected based on a particular design technique. For example, a two-dimensional rigorous grating theory technique, a thin film theory technique, a simulated annealing and steepest descent technique, or the like may be used to identify a pattern or arrangement of gaps and stacks in cooperation with the refractive index and thickness of each layer to provide a particular phase delay at a particular wavelength for which stacks and gaps provide an anti-reflection functionality. Alternatively, the desired diffractive and reflective properties of the grating may be obtained with more than or fewer than the five layers shown in FIG. 3D.

Although described herein in terms of a particular set of thicknesses, other thicknesses are possible to achieve an anti-reflective functionality, a particular phase delay, a particular refractive index, or the like. In some implementations, layers 364 of a stack may be formed using a deposition procedure. For example, an Si thin film layer, a SiO₂ thin film layer, or the like may be deposited onto a surface of substrate 362 to form a set of anti-reflective layers that are configured as a set of stacks and a set of gaps. Additionally, or alternatively, the stacks and the gaps may be formed using an etching procedure. For example, after deposition of Si, SiO₂, or the like to form thin film layers on substrate 362, the layers may be masked using a single masking step and etched using a single etching step to form gaps and stacks.

As shown in FIG. 3E, another example of a DOE 380 may include a variable fill factor and a three or more level relief pattern. For example, stacks of the DOE 380 may include multiple layers of thin films on a surface of substrate 382 to form a multi-level DOE with varying fill factors. In this case, a stack may include a first layer 384-1 of Si, a second layer 384-2 of SiO₂, a third layer 384-3 of Si, a fourth layer 384-4 of SiO₂, and a fifth layer 384-5 of Si, a sixth layer 384-6 of SiO₂, a seventh layer 384-7 of Si, and an eighth layer 384-8 of SiO₂. In some implementations, layers 384-1 and 384-2 may form a first index-matched pair, layers 384-4 and 384-5 may form a second index-matched pair, and layers 384-7 and 384-8 may form a third index-matched pair. Further, layers 384-1 and 384-2 may be a first anti-reflection structure 386-1, layers 384-4 and 384-5 may form a second anti-reflection structure 386-2, and layers 384-7 and 384-8 may form a third anti-reflection structure 386-3. In contrast, layers 384-3 and 384-6 may be spacers between index-matched pairs that may be selected to control an effective refractive index of the DOE 380. Alternatively, in some implementations, the various layers in a stack may have respective indexes, thicknesses, and/or other properties that work in concert to simultaneously provide anti-reflection and phase delay properties.

In another example, a metal layer may be used as a layer of the DOE 380. For example, rather than forming layers 384-1 and 384-2 onto a top surface of the substrate 382, a metal layer may be used to replace anti-reflection structure 386-1 and the substrate 382, and layer 384-3 may be formed onto a top surface of the metal layer.

In the DOE 380, each carrier period includes multiple stacks and multiple gaps to configure a fill factor of each carrier period. For example, a first carrier period from 0 dc to 1 dc includes a first stack with a first height (e.g., layers 384-1 to 384-5) and width and a second stack with a second height (e.g., layers 384-1 to 384-8) and width to form a first fill factor ff₁. In contrast, a second carrier period from 1 dc to 2 dc includes a third stack with the first height (e.g., layers 384-1 to 384-5) and another width and a fourth stack with the second height (e.g., layers 384-1 to 384-8) and another width to form a second fill factor ff₂. In this case, each of the first to fourth stacks is associated with a different width to form the first fill factor and the second fill factor.

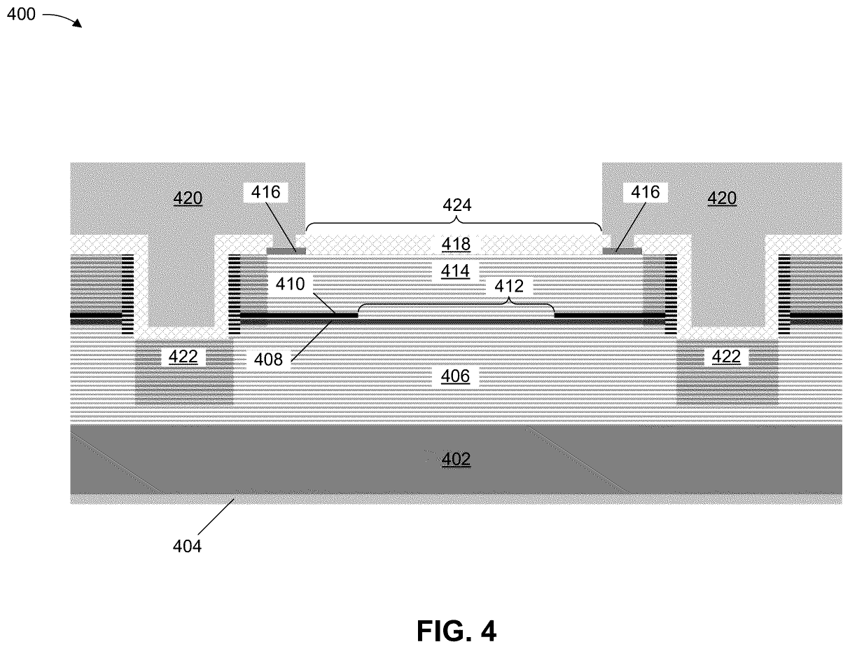

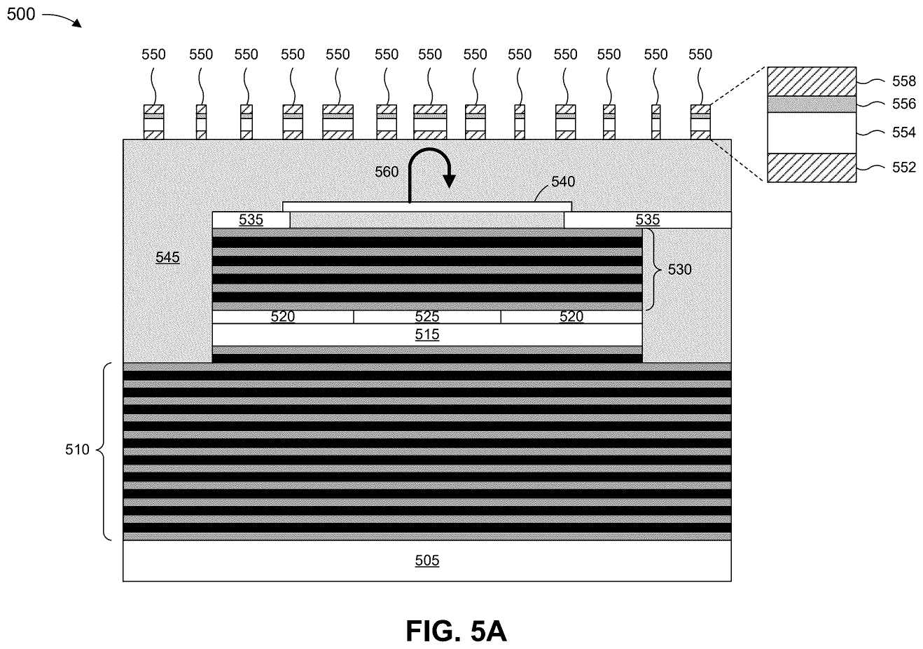

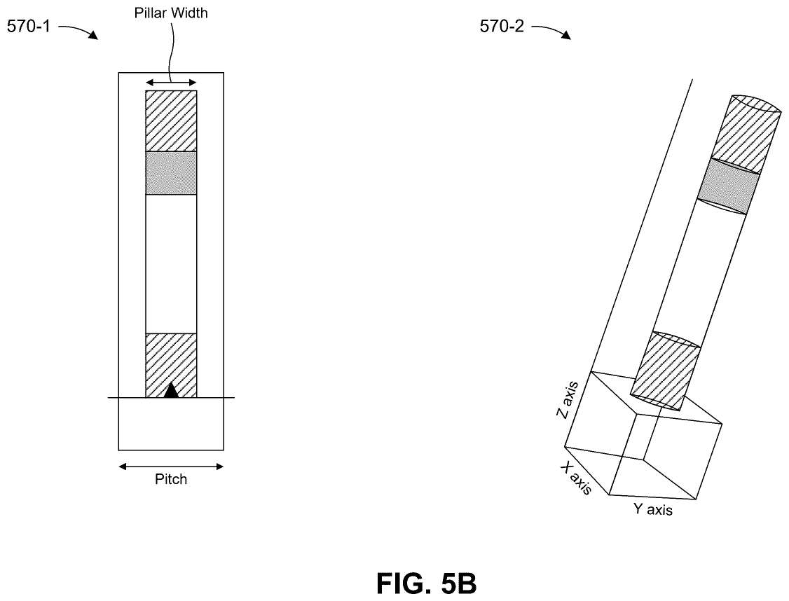

In another example, a carrier period may include multiple gaps associated with different depths from a top surface of a thin film layer towards a top surface of a substrate. In some implementations, the DOE 380 may be formed onto a wafer, such as a VCSEL. For example, DOE 380 may be formed onto a wafer including one or more emitters oriented to emit through the substrate 382 and toward the top surface of substrate 382. Additionally, or alternatively, the DOE 380 may be formed onto a wafer including another optical element, such as a vertical emitter array, a sensor, a sensor array, or the like. Further details related to an example structure for a VCSEL are provided herein with reference to FIG. 4, and further details related to an example DOE that may be integrated with a VCSEL are provided herein with reference to FIGS. 5A-5B.

As shown in FIG. 3F, another example implementation of an optical element 390 may include a substrate 392 with a first DOE 394-1 on a first, top surface of substrate 392 and a second DOE 394-2 on a second, bottom surface of substrate 392. For example, thin film layers may be deposited and/or formed on the top surface and the bottom surface of substrate 392 to form a set of DOEs 394. In this way, a difficulty in aligning multiple DOEs may be reduced relative to mounting multiple DOEs on multiple substrates and aligning the multiple substrates. In some implementations, corresponding carrier periods of the DOEs 394-1 and 394-2 may be associated with common fill factors. For example, both DOE 394-1 and DOE 394-2 may be associated with a first fill factor, ff₁, for a first carrier period from 0 dc to 1 dc, and may be associated with a second fill factor, ff₂, for a second carrier period from 1 dc to 2 dc. Additionally, or alternatively, corresponding carrier periods of the DOEs 394-1 and 394-2 may be associated with different fill factors.

As shown in FIG. 3G, another example implementation of an optical element 395 may include a substrate 396 with a DOE 397 and a fill material 398. In this case, the fill material 398 may be disposed into gaps between stacks and/or onto a surface of the stacks and/or the substrate 396 to create a planar surface for the optical element 395. In this way, the fill material 398 may seal the optical element 395 to prevent degradation of optical performance resulting from a presence of water, humidity, or the like. In some implementations, the fill material 398 may be associated with a particular refractive index matched to the stacks, such as a refractive index of approximately 1.6 to create a 1.9 differential with stacks with a refractive index of approximately 3.5. In this way, a phase delay is maintained when optical element 395 is in contact with, for example, water.

Although described herein in terms of a set of 5 layers, 8 layers, or the like, other quantities of layers may be used, such as additional layers, fewer layers, or a different combination of layers. For example, FIGS. 5A-5B illustrate example DOEs that include multiple layers that are formed from certain materials, arranged in a particular sequence, and have particular thicknesses designed to suppress back reflections (e.g., provide antireflective properties), increase transmission, and reduce absorption.

As indicated above, FIGS. 3A-3G are provided as examples. Other examples may differ from what is described with regard to FIGS. 3A-3G.

FIG. 4 is a diagram illustrating an example VCSEL 400. In some implementations, the VCSEL 400 may be included in an array of emitters (e.g., an array of VCSELs 400). In some implementations, as illustrated in FIG. 4, the VCSEL 400 is a top-emitting emitter. Alternatively, in some implementations, the VCSEL 400 may be a bottom-emitting emitter (e.g., with a similar structure to that shown in FIG. 4, with modifications to enable bottom-emitting). As shown in FIG. 4, the VCSEL 400 may include a substrate 402, a bottom metal 404, a bottom mirror structure 406, a cavity including one or more an active regions (herein referred to as cavity region 408), a confinement layer 410 that forms a confinement aperture 412, a top mirror structure 414, a top contact layer 416, a dielectric layer 418, a top metal 420, and one or more isolation implants 422. As shown, one or more layers of the VCSEL 400 (e.g., the top contact layer 416, the dielectric layer 418, the top metal 420, or the like) may form an output aperture 424.

Substrate 402 includes a supporting material upon which, or within which, one or more layers or features of the VCSEL 400 are grown or fabricated. In some implementations, the substrate 402 includes an n-type material. In some implementations, the substrate 402 includes a semi-insulating type of material. In some implementations, the semi-insulating type of material may be used when the VCSEL 400 includes one or more bottom-emitting emitters in order to reduce optical absorption from the substrate 402. In such an implementation, the VCSEL 400 may include a contact buffer in or near the bottom mirror structure 406. In some implementations, the substrate 402 may be formed from a semiconductor material, such as GaAs, indium phosphide (InP), or another type of semiconductor material. In some implementations, a bottom contact (e.g., a bottom n-contact) of the VCSEL 400 can be made from a backside of the substrate 402. In some implementations, the bottom contact of the VCSEL 400 can be made from a front side of the VCSEL 400. In some implementations, the front side contact can be achieved by, for example, etching a mesa step or trench to the substrate 402, or inserting a contact buffer in or near the bottom mirror structure 406.

Bottom metal 404 includes a metal layer on a bottom surface of the substrate 402 (e.g., at a backside of the VCSEL 400). In some implementations, the bottom metal 404 is formed from an n-type material. In some implementations, the bottom metal 404 is a layer that makes electrical contact with the substrate 402. In some implementations, the bottom metal 404 serves as an anode for the VCSEL 400. In some implementations, the bottom metal 404 may include an annealed metallization layer, such as a gold-germanium-nickel (AuGeNi) layer, a palladium-germanium-gold (PdGeAu) layer, among other examples.

Bottom mirror structure 406 is a bottom reflector of an optical resonator of the VCSEL 400. For example, the bottom mirror structure 406 may include a distributed Bragg reflector (DBR), a dielectric mirror, or another type of mirror structure. In some implementations, the bottom mirror structure 406 is formed from an n-type material. In some implementations, the bottom mirror structure 406 is on a top surface of the substrate 402. In some implementations, the bottom mirror structure 406 may have a thickness in a range from approximately 3.5 μm to approximately 9 μm, such as 5 μm. In some implementations, the bottom mirror structure 406 includes a set of layers (e.g., aluminum gallium arsenide (AlGaAs) layers) grown using a metal-organic chemical vapor deposition (MOCVD) technique, a molecular beam epitaxy (MBE) technique, or another technique.

Cavity region 408 includes one or more layers where electrons and holes recombine to emit light and define the emission wavelength range of the VCSEL 400. For example, the cavity region 408 may include one or more active regions in the form of one or more quantum wells (QWs). In some implementations, the cavity region 408 may include one or more cavity spacer layers (e.g., to enable epitaxial growth to have sufficient room for ramping compositions or temperature). In some implementations, the one or more cavity spacer layers may reduce strain between active regions of the cavity region 408 and/or may mitigate thermal issues of laser operation of the VCSEL 400. In some implementations, the one or more cavity spacer layers may include an oxidation layer. An optical thickness of the cavity region 408 (including the one or more active regions and any cavity spacer layers), the top mirror structure 414, and the bottom mirror structure 406 defines the resonant cavity wavelength of the VCSEL 400, which may be designed within an emission wavelength range of the cavity region 408 to enable lasing. In some implementations, the cavity region 408 may be formed on the bottom mirror structure 406. In some implementations, the cavity region 408 may have a thickness in a range from approximately 0.006 μm to approximately 0.5 μm, such as 0.15 μm or 0.30 μm. In some implementations, the cavity region 408 includes a set of layers grown using an MOCVD technique, an MBE technique, or another technique.

Confinement layer 410 is a layer that provides optical and/or electrical confinement for the VCSEL 400. In some implementations, the confinement layer 410 enhances carrier and mode confinement of the VCSEL 400 and, therefore, can improve performance of the VCSEL 400. In some implementations, the confinement layer 410 is on, under, or in the cavity region 408. In some implementations, there may be one or more spacer layers or mirror layers (e.g., DBRs) between the confinement layer 410 and the cavity region 408. In some implementations, the confinement layer 410 is on a side of the cavity region 408 nearer to the bottom mirror structure 406 (e.g., on a substrate side of the cavity region 408). In some implementations, the confinement layer 410 is on a side of the cavity region 408 nearer to the top mirror structure 414 (e.g., on a non-substrate side of the cavity region 408).

In some implementations, the confinement layer 410 is an oxide layer formed as a result of oxidation of one or more epitaxial layers of the VCSEL 400. For example, the confinement layer 410 may be an aluminum oxide (Al₂O₃) layer formed as a result of oxidation of an epitaxial layer (e.g., an AlGaAs layer, an AlAs layer, or the like). In some implementations, the confinement layer 410 may have a thickness in a range from approximately 0.007 μm to approximately 0.04 μm, such as 0.02 μm. In some implementations, oxidation trenches (shown as filled in FIG. 4) etched around the VCSEL 400 may allow steam to access the epitaxial layer(s) from which the confinement layer 410 is formed. In some implementations, the oxidation trenches may not fully enclose the confinement layer 410. For example, the oxidation trenches may follow the general shape of the confinement region, but there may be gaps between adjacent oxidation trenches. In some implementations, the confinement layer 410 may follow the general geometric shape, but may have variations associated with shapes or locations of the oxidation trenches and/or variations associated with an oxidation rate. In some implementations, in addition to the confinement layer 410, the VCSEL 400 may include one or more other types of structures or layers that provide current confinement, such as an implant passivation structure, a mesa isolation structure, a moat trench isolation structure, a buried tunnel junction, or the like. Additionally, or alternatively, such other types of structures or layers for providing current confinement may be included in or integrated with the confinement layer 410.

In some implementations, the confinement layer 410 defines the confinement aperture 412. Thus, in some implementations, the confinement aperture 412 is an optically active aperture defined by the confinement layer 410. In some implementations, a size (e.g., a width in a given direction) of the confinement aperture 412 is in a range from approximately 1 μm to approximately 30 μm, such as 5 μm or 8 μm. In some implementations, the confinement aperture 412 may be formed by oxidation (e.g., when the confinement layer 410 is an oxidized layer). Additionally, or alternatively, the confinement aperture 412 may be formed by other means, such as by implantation, diffusion, regrowth (e.g., using a high resistance layer, a current blocking layer, a tunnel junction, or the like), or an air gap, among other examples.

Top mirror structure 414 is a top reflector of the optical resonator of the VCSEL 400. For example, the top mirror structure 414 may include a DBR, a dielectric mirror, or the like. In some implementations, the top mirror structure 414 is formed from a p-type material. In some implementations, the top mirror structure 414 may have a thickness in a range from approximately 1 μm to approximately 6 μm, such as 3 μm. In some implementations, the top mirror structure 414 includes a set of layers (e.g., AlGaAs layers) grown using an MOCVD technique, an MBE technique, or another technique. In some implementations, the top mirror structure 414 is grown on or over the cavity region 408.

In some implementations, a total thickness from a bottom surface of the bottom mirror structure 406 to a top surface of the top mirror structure 414 may be in a range from, for example, approximately 4.5 μm to approximately 26.4 μm, such as approximately 8.6 μm. In some implementations, a thickness of one or more of the layers of the VCSEL 400 may be selected in order to provide a structure that achieves high reflectivity (e.g., greater than approximately 99% reflectivity). In some implementations, a smaller total thickness may facilitate growth time reduction of the VCSEL 400 or stress reduction within the VCSEL 400.

The top contact layer 416 makes electrical contact with the top mirror structure 414 through which current may flow. In some implementations, the top contact layer 416 includes an annealed metallization layer. For example, the top contact layer 416 may include a chromium-gold (Cr—Au) layer, a gold-zinc (Au—Zn), a titanium-platinum-gold (TiPtAu) layer, a gold-germanium-nickel (AuGeNi) layer, a palladium-germanium-gold (PdGeAu) layer, or the like. In some implementations, the top contact layer 416 has a thickness in a range from approximately 0.03 μm to approximately 0.3 μm, such as 0.2 μm. In some implementations, the top contact layer 416 has a ring shape, a slotted ring shape, a tooth wheel shape, or another type of circular or non-circular shape (e.g., depending on a design of the VCSELs in the VCSEL 400).

Dielectric layer 418 is a layer that at least partially insulates the top metal 420 from one or more other layers or features (e.g., sidewalls of trenches). In some implementations, the dielectric layer 418 may include, for example, SiNx, SiO₂, a polymer dielectric, or another type of insulating material.

The top metal 420 is a top metal layer at a front side of the VCSEL 400. In some implementations, the top metal 420 is formed from a p-type material. Alternatively, in some implementations, the top metal 420 is formed from an n-type material. In some implementations, the top metal 420 may be a layer that makes electrical contact with the top contact layer 416. In some implementations, the top metal 420 may serve as a cathode for the VCSEL 400.

Isolation implant 422 is a region to prevent free carriers from reaching edges of trenches and/or to isolate adjacent VCSELs 400 from one another (e.g., if the trenches do not fully enclose the VCSELs of the VCSEL 400). Isolation implant 422 may include, for example, an ion implanted material, such as a hydrogen/proton implanted material or a similar implanted element to reduce conductivity.

The output aperture 424 is an aperture of the VCSEL 400 through which light is emitted. As shown, the output aperture 424 may be defined by one or more layers of the VCSEL 400, such as the top contact layer 416, the dielectric layer 418, or the top metal 420. In some implementations, a size (e.g., a width in a given direction) of the output aperture 424 is in a range from approximately 1 μm to approximately 30 μm, such as 5 μm or 8 μm.

The number, arrangement, thicknesses, order, symmetry, or the like, of layers shown in FIG. 4 are provided as an example. In practice, the VCSEL 400 may include additional layers, fewer layers, different layers, differently constructed layers, or differently arranged layers than those shown in FIG. 4. For example, as noted above, the VCSEL 400 may in some implementations be a bottom-emitting VCSEL, and a structure similar to that shown in FIG. 4 may be utilized for bottom emission, with appropriate modification to support bottom emission (e.g., an output aperture can be formed at a bottom of the VCSEL rather than a top of the VCSEL). Additionally, or alternatively, a set of layers (e.g., one or more layers) of the VCSEL 400 may perform one or more functions described as being performed by another set of layers of the VCSEL 400, and any layer may include more than one layer.

FIG. 5A is a diagram illustrating an example 500 of a VCSEL with an integrated DOE having antireflective properties. For example, as described herein, the integrated DOE may comprise an array of meta-atom unit cells 550 that form a multi-layer meta-surface, or meta-lens, for beam shaping, suppressing back reflections, improving transmission, and/or reducing absorption of light emitted by the VCSEL. In some implementations, the VCSEL may be included in an array of emitters (e.g., an array of VCSELs that each have an integrated DOE with the properties described herein). In some implementations, as illustrated in FIG. 5A, the VCSEL is a top-emitting emitter having a structure similar to the VCSEL 400 shown in FIG. 4. For example, as shown in FIG. 5A, the VCSEL includes a substrate 505, a bottom mirror structure 510 (e.g., a set of n-type DBRs, which are DBRs doped with an n-type material) on the substrate 505, an active region 515, an oxidation aperture 520 defining a cavity region 525, a top mirror structure 530 (e.g., a set of p-type DBRs, which are DBRs doped with a p-type material), and a metal contact ring 535 that defines an output aperture 540 through which light is emitted. In some implementations, the VCSEL may not have an output aperture 540. Although the VCSEL shown in FIG. 5A is a top-emitting emitter, some implementations described herein may be used for a bottom-emitting emitter (e.g., with a similar structure to that shown in FIG. 5A, with modifications to enable bottom-emitting).

As described herein, a meta-surface is a structure that employs a subwavelength “meta-atom” pattern on a dielectric surface to manipulate incident light. The meta-atom pattern may modify a phase profile of an incident light beam such that the beam may be bent (or redirected). FIG. 5A illustrates an example where an array of meta-atom unit cells 550 form a meta-surface that may be configured as a DOE integrated with the VCSEL. For example, meta-atoms are nanoscale structures with varying shapes and/or sizes, and a position of the meta-atoms across the meta-surface can be configured to control interaction with emitted light. Accordingly, because a meta-surface has a subwavelength scale feature size and multi-functionality, a meta-surface may be used as an optical component (e.g., in connection with a VCSEL for applications such as focusing, diffusing laser beam profiles, diffracting light, and/or polarization control, among other examples). In some implementations, the meta-surface may be used to collimate an output beam and narrow the divergence of the laser beam emitted by the VCSEL. In some implementations, the meta-surface may be integrated with the VCSEL. For example, as shown in FIG. 5A, the VCSEL may include an integrated meta-surface with antireflective functionality, which may minimize back reflections to a laser cavity and thereby mitigate back reflections that may otherwise perturb characteristics of the VCSEL. For example, the VCSEL may include an integrated meta-surface with an antireflective property that is integrated with the VCSEL using meta-atoms to suppress back reflections from a substrate or base layer 545 under the meta-surface and/or back reflections from the air interface or other layer(s) above the meta-surface.

As described herein, a high-quality beam with a narrow beam divergence is desired for many VCSEL applications, such as short-range optical communication systems, facial recognition and gesture detection in consumer electronics, ToF or structured light cameras, LiDAR or other sensing applications, and/or display applications, among other examples. In some cases, techniques to eliminate higher order modes and reduce beam divergence in a VCSEL include using small confinement apertures and/or mode filters. However, these techniques introduce losses to lasing modes, dominantly to high-order modes (HOMs), and therefore impose penalties on VCSEL performance. Accordingly, as described herein, the VCSEL shown in FIG. 5A includes an integrated DOE, or meta-surface, that may be used to split, shape, or focus a beam emitted by the VCSEL and suppress back reflections with minimal effect on performance of the VCSEL.

For example, in some implementations, the meta-surface may include an array of meta-atom unit cells 550, which are sub-wavelength scale structures (or “nano structures”) that may be etched into layers of varying index materials. The meta-atom unit cells 550 may be associated with a shared set of parameters, such as a width, a quantity of layers, a material used for each layer, a sequence of layers, and/or a thickness of each layer. The meta-atom unit cells 550 may have a stack-like structure (e.g., as shown in FIGS. 3D-3G), and the structure may include pillars or posts having a cylindrical shape, a rectangular shape (e.g., a rectangular prism), a square shape (e.g., a cuboid), a triangular shape (e.g., a pyramid), or another suitable shape. Additionally, or alternatively, the meta-atom unit cells 550 may be fabricated in the form of holes, which may be more physically robust in comparison to pillars and/or posts. In cases where the meta-atom unit cells 550 are fabricated in the form of holes, the holes may be round, square, triangular, or another suitable shape. Furthermore, the meta-atom unit cells 550 can be arranged in a rectangular lattice, a square lattice, a hexagonal lattice, or another suitable pattern.

In some implementations, as shown in FIG. 5A, to fabricate the VCSEL with the integrated DOE or meta-surface, a substrate layer 545 may be deposited on the top surface of the VCSEL. For example, the substrate layer 545 may form a base layer for the integrated DOE or meta-surface comprising the array of meta-atom unit cells 550. In some implementations, the substrate layer 545 that provides the base layer or platform for the meta-surface may comprise any suitable material that is transparent at an operating wavelength associated with the VCSEL. For example, the substrate layer 545 may be formed from an epoxy-based polymer or photoresist, such as SU-8, poly(methyl methacrylate) (PMMA), SiO₂, and/or another material transparent at an operating wavelength associated with the VCSEL. In some implementations, the substrate layer 545 may have a thickness that depends on a deposition and/or patterning technique used to fabricate the meta-surface. As described herein, because the meta-surface has antireflective properties to suppress back reflections, the thickness of the substrate layer 545 may not be subject to constraints that relate to separating the meta-surface from the emitting surface of the VCSEL to avoid back reflections (e.g., the substrate layer 545 may be made “thin” to maximize output light because the antireflective meta-surface suppresses back reflections from the meta-surface).

In some implementations, the meta-atom unit cells 550 may each include a meta-atom layer, which may include meta-atoms fabricated from a high index material that has low to moderate losses at the operating wavelength of the VCSEL. For example, in some implementations, the meta-atoms may be formed in a-Si, GaAs, SiNx, and/or TiO₂, among other examples. In some implementations, a layer of the high index material may be deposited over the substrate layer 545 to a particular thickness, and the meta-atoms may then be etched into the layer of high index material. FIG. 5A illustrates a VCSEL with an integrated DOE or meta-surface that comprises an array of meta-atom unit cells 550 that are formed with an a-Si meta-atom layer with a pillar structure arranged in a square lattice, although other suitable materials, structures, and/or patterns may be used as described herein.

In some implementations, as shown by reference number 560, the DOE or meta-surface may be integrated with the top-emitting VCSEL to suppress back reflections in which light couples back into the cavity of the VCSEL. For example, back reflections can perturb the operating characteristics of a VCSEL, such as the lasing wavelength and/or threshold current. Accordingly, as shown in FIG. 5A, the meta-atom unit cells forming the DOE or meta-surface may have a multi-layer meta-atom structure to mitigate the effect of back reflections. The multi-layer meta-atom structure, in combination with a meta-atom high index layer, may behave or exhibit properties of an antireflective coating. For example, in some implementations, the multi-layer meta-atom structure may include a first set of layers that are made from one or more high index dielectric materials and a second set of layers that are made from one or more low index dielectric materials, where the first set of layers and the second set of layers may be arranged in an identical sequence in each meta-atom unit cell 550. Furthermore, each layer of the meta-atom cells 550 may have a particular thickness, where the thickness of the layers and the sequence of high index and low index dielectric materials may be optimized to reduce reflection, increase transmission, and reduce absorption. For example, FIG. 5A illustrates meta-atom unit cells 550 that include a first high index layer 552 formed on the substrate (or base) layer 545 (e.g., an SiNx layer), a low index layer 554 formed on the first high index layer 552 (e.g., an SiO₂ layer), a second high index layer 556 formed on the low index layer 554 (e.g., an a-Si layer), and a third high index layer 558 formed on the second high index layer 556 (e.g., an SiNx layer). In some implementations, the second high index layer 556 may be a meta-atom layer. Although FIG. 5A illustrates a particular sequence and combination of high index and low index layers, other sequences and/or combinations of high index and low index layers may be used. As described herein, in any sequence of layers used to form the meta-atom unit cells 550, only the meta-atom layer (e.g., layer 556 in the example illustrated in FIG. 5A) is required to be a high index material, and other layers may be made from high index or low index materials depending on one or more parameters to be optimized (e.g., antireflection, transmission, and/or absorption).

Additionally, or alternatively, the meta-atom unit cells 550 may include multiple layers arranged in other suitable sequences, such as any of the sequences associated with the stacked shown in FIGS. 3D-3G, any other sequence described herein, or any other suitable sequence based on one or more parameters to be optimized. For example, in some implementations, and with reference to FIG. 3D, the meta-atom units cells 550 may comprise a first layer 364-1 of Si, a second layer 364-2 of SiO₂, a third layer 364-3 of Si, a fourth layer 364-4 of SiO₂, and a fifth layer 364-5 of Si, where layers 364-1 and 364-2 form a first index-matched pair, layers 364-4 and 364-5 form a second index-matched pair, and layer 364-3 is a spacer between the index-matched pairs that may be selected to control an effective index of the DOE.

In some implementations, as described herein and shown in FIG. 5A, the DOE or meta-surface comprising the array of meta-atom unit cells 550 may be integrated with a top-emitting VCSEL. As shown in FIG. 5A, the VCSEL has a top surface, and the top surface may be spin-coated with a material (e.g., an SU-8 polymer) to form the substrate layer 545 that provides the base layer or platform for the DOE or meta-surface. Subsequently, a relatively thick layer of a high index material, such as a-Si, may be deposited on the substrate layer 545, and meta-atom unit cells 550 (e.g., pillars, posts, holes, or the like) with a fixed period may be etched in the thick layer of high index material to form the meta-surface. In some implementations, the meta-atom unit cells 550 may be designed for a wavelength in a range from 850 nm to 1480 nm, and the thicknesses of the various layers (e.g., layers 552, 554, 556, and 558 in the illustrated example) may be optimized to minimize back reflections, increase transmission, and/or reduce absorption at the operating wavelength. For example, in a use case where the integrated DOE or meta-surface is designed for a wavelength of 940 nm, the first high index layer 552 and the third high index layer 556 may be SiNx layers with a thickness of approximately 150 nm, the low index layer 554 may comprise be an SiO₂ layer with a thickness of approximately 330 nm, and the second high index (meta-atom) layer 556 may be an a-Si layer with a thickness of approximately 100 nm. As used herein, the term “approximately” relative to a given value may cover a range that is +1% relative to the given value (e.g., the second high index layer 556 may have a thickness in a range from 97 to 103 nm). The thicknesses of the various layers forming the meta-atom unit cells 550 may vary depending on the operating wavelength, and depending on the quantity, sequence, and/or materials used for the high index and low index layers. Additionally, or alternatively, the thicknesses, materials, sequence, widths, and/or other parameters associated with the meta-atom unit cells 550 may be varied to minimize reflection, maximize transmission, minimize absorption, and/or optimize any suitable combination or permutation thereof.

In some implementations, as described herein, the meta-atom unit cells 550 may each comprise one or more high index dielectric layers and one or more low index dielectric layers, which are arranged in an identical sequence and have identical thicknesses in each meta-atom unit cell 550. For example, FIG. 5B illustrates a cross-sectional view 570-1 and a corresponding three-dimensional view 570-2 of a meta-atom unit cell 550, where each meta-atom unit cell 550 includes one or more high index layers (including at least a meta-atom layer) and one or more low index layers that are arranged in an identical sequence and have the same thicknesses. In addition, the meta-atom unit cells 550 have the same width, which may be selected to optimize one or more of antireflection, transmission, and/or absorption properties. For example, as shown in FIG. 5B, the meta-atom unit cells 550 may all have the same width, or pitch, and the meta-atom unit cells 550 may each have a pillar width that may be the same or variable among the meta-atom unit cells 550 (e.g., depending on a desired output phase profile). Furthermore, to operate in a sub-wavelength regime, a pitch of the meta-surface may have an upper limit of

$$\frac{λ}{{n}_{substrate}} ,$$

where λ is a wavelength and n_{substrate} is a refractive index of the substrate layer 545 (e.g., for the configuration shown in FIG. 5A, the pitch of the meta-surface may have a value that does not exceed 600 nm, such as 250 nm). For example, the pitch of the meta-surface may be defined by a period of the meta-atom unit cells 550 within the lattice.

As indicated above, FIGS. 5A-5B are provided as an example. Other examples may differ from what is described with regard to FIGS. 5A-5G.

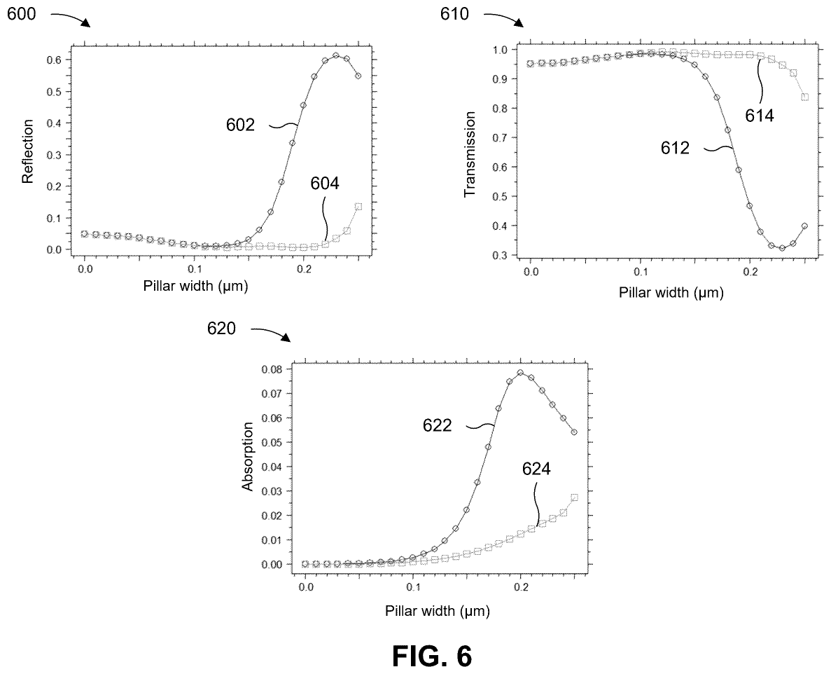

FIG. 6 is a diagram illustrating example performance characteristics 600 associated with an antireflective DOE (e.g., the DOE or meta-surface described herein with reference to FIGS. 5A-5B). For example, as described herein, an antireflective DOE or meta-surface may include multiple layers, including a set of high index dielectric layers that includes at least a meta-atom layer, and a set of low index dielectric layers. The high index and low index dielectric layers may be arranged in an identical sequence in each meta-atom unit cell, and the layers may have the same thickness and width (or pitch), and may be made from the same material in each meta-atom unit cell. In addition, each meta-atom unit cell may have a respective pillar width that may be the same or variable among the meta-atom unit cells 550 (e.g., depending on a desired output phase profile). Furthermore, the thicknesses, materials, sequence, width, and/or other parameters associated with the meta-atom unit cells may be selected to minimize reflection, maximize transmission, minimize absorption, and/or optimize any suitable combination or permutation thereof in accordance with an operating wavelength.

For example, FIG. 6 illustrates examples 600, 610, and 620 of performance metrics associated with a VCSEL with and without the integrated multi-layer meta-surface for meta-atoms with different pillar widths. In particular, examples 600, 610, and 620 respectively depict reflection, transmission, and absorption performance for a VCSEL having a 940 nm operating wavelength, with and without a meta-surface that includes four layers with the thicknesses and sequence of layers described herein (e.g., a first layer made from SiNx with a 150 nm thickness, a second layer made from SiO₂ with a 330 nm thickness, a third layer made from a-Si with a 100 nm thickness, and a fourth layer made from SiNx with a 150 nm thickness).

Referring to FIG. 6, and to example 600, curve 602 depicts reflection properties associated with a VCSEL without an integrated meta-surface, and curve 604 depicts reflection properties associated with the VCSEL with an integrated meta-surface for different pillar widths. Similarly, referring to example 610, curve 612 depicts transmission properties associated with the VCSEL without the integrated meta-surface, and curve 614 depicts transmission properties associated with the VCSEL with the integrated meta-surface for different pillar widths. Referring to example 620, curve 622 depicts absorption properties associated with the VCSEL without the integrated meta-surface, and curve 624 depicts absorption properties associated with the VCSEL with the integrated meta-surface for different pillar widths. The reflection, transmission, and absorption efficiencies shown in FIG. 6 reflect calculations made using a rigorous coupled-wave analysis (RCWA) method, and are plotted with respect to pillar widths. As shown in FIG. 6, the design of the VCSEL with the integrated meta-surface provides a significant improvement over a VCSEL without the integrated meta-surface. For example, example 600 shows that the average reflection over the pillar widths is reduced from 17.5% to 2.7%, example 610 shows that the average transmission over the pillar widths is increased from 80% to 96.7%, and example 620 shows that the average absorption over the pillar widths is reduced from 2.64% to 0.61%. As shown by examples 600, 610, and 620, the integrated meta-surface provides better reflection, transmission, and absorption performance at pillar widths above approximately 0.1 μm, and the performance difference is largest at a pillar width of approximately 0.2 μm.

As indicated above, FIG. 6 is provided as an example. Other examples may differ from what is described with regard to FIG. 6.

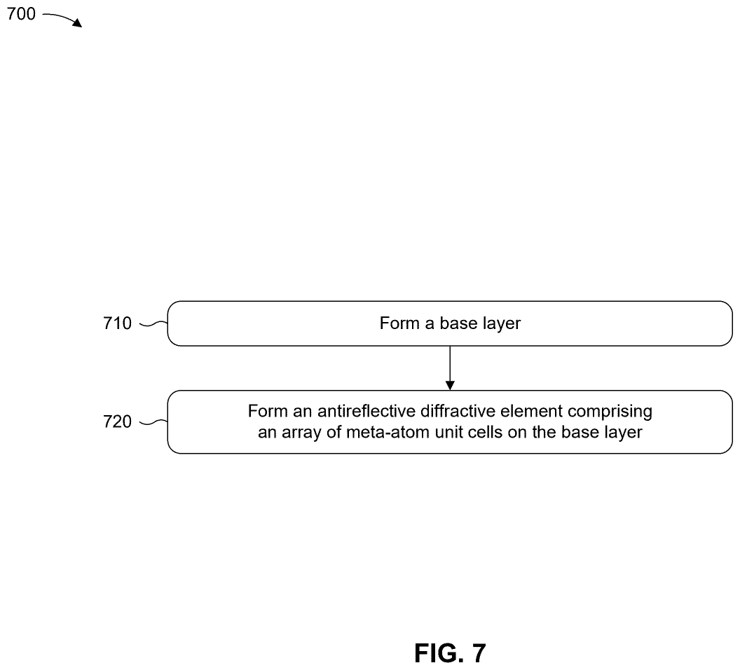

FIG. 7 is a flowchart of an example method 700 for fabricating an optical system that includes an antireflective DOE. In some implementations, one or more process blocks of FIG. 7 are performed by a deposition system and/or by another device or a group of devices separate from or including the deposition system.

As shown in FIG. 7, method 700 may include forming a base layer (block 710). For example, the deposition system may form a base layer 545, as described above.

As further shown in FIG. 7, method 700 may include forming an antireflective DOE comprising an array of meta-atom unit cells on the base layer (block 720). For example, the deposition system may form an antireflective DOE comprising an array of meta-atom unit cells on the base layer 545, as described above. In some implementations, the meta-atom unit cells each comprise a first set of layers formed from one or more high index dielectric materials (e.g., layers 552, 556, 558), wherein the first set of layers includes a meta-atom layer (e.g., layer 556), and a second set of layers formed from one or more low index dielectric materials (e.g., layer 554). In some implementations, the first set of layers and the second set of layers are arranged in an identical sequence in each of the meta-atom unit cells.

Method 700 may include additional implementations, such as any single implementation or any combination of implementations described below and/or in connection with one or more other processes described elsewhere herein.

In a first implementation, the meta-atom unit cells comprise pillars, posts, or triangle structures arranged in a lattice.

In a second implementation, alone or in combination with the first implementation, the meta-atom unit cells comprise holes arranged in a lattice.

In a third implementation, alone or in combination with one or more of the first and second implementations, the one or more high index dielectric materials comprise one or more of a-Si, GaAs, SiNₓ, or TiO₂.

Although FIG. 7 shows example blocks of method 700, in some implementations, method 700 includes additional blocks, fewer blocks, different blocks, or differently arranged blocks than those depicted in FIG. 7. Additionally, or alternatively, two or more of the blocks of method 700 may be performed in parallel.

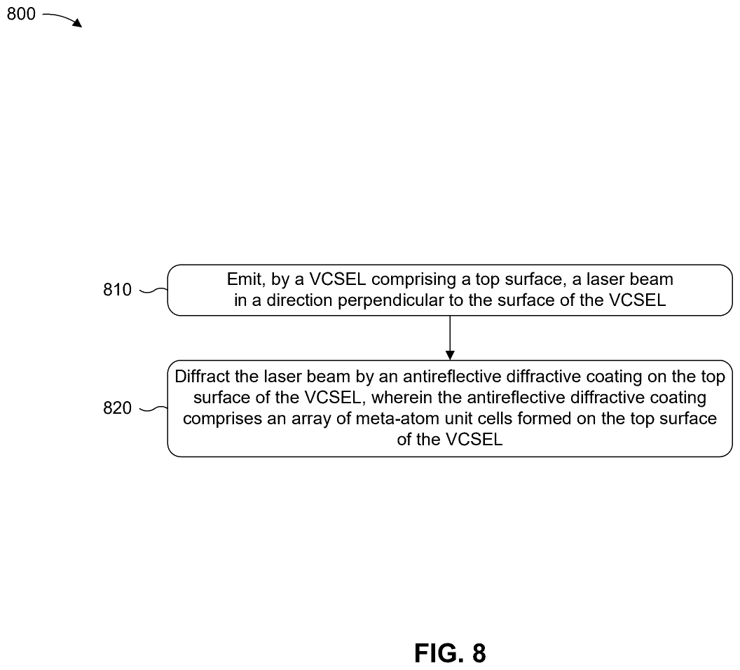

FIG. 8 is a diagram illustrating an example method 800 for operating an optical system that includes an antireflective DOE. In some implementations, one or more process blocks of FIG. 8 are performed by an optical system and/or by another device or a group of devices separate from or including the optical system.

As shown in FIG. 8, method 800 may include emitting a laser beam in a direction perpendicular to the top surface of the VCSEL (block 810). For example, the optical system may include a VCSEL configured to emit a laser beam in a direction perpendicular to the top surface of the VCSEL, as described above.

As further shown in FIG. 8, method 800 may include diffracting the laser beam by an antireflective diffractive coating on the top surface of the VCSEL, wherein the antireflective diffractive coating comprises an array of meta-atom unit cells formed on the top surface of the VCSEL (block 820). For example, the antireflective diffractive coating may diffract the laser beam emitted by the VCSEL, as described above. In some implementations, the antireflective diffractive coating comprises an array of meta-atom unit cells formed on the top surface of the VCSEL, and the meta-atom unit cells each comprise a first set of layers formed from one or more high index dielectric materials and a second set of layers formed from one or more low index dielectric materials. In some implementations, the first set of layers includes a meta-atom layer.

Method 800 may include additional implementations, such as any single implementation or any combination of implementations described below and/or in connection with one or more other processes described elsewhere herein.

In a first implementation, the first set of layers and the second set of layers are arranged in an identical sequence in each of the meta-atom unit cells.

In a second implementation, alone or in combination with the first implementation, the meta-atom unit cells are arranged in a lattice.

In a third implementation, alone or in combination with one or more of the first and second implementations, the meta-atom layer is a-Si.

Although FIG. 8 shows example blocks of method 800, in some implementations, method 800 includes additional blocks, fewer blocks, different blocks, or differently arranged blocks than those depicted in FIG. 8. Additionally, or alternatively, two or more of the blocks of method 800 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical system, comprising:
a vertical-cavity surface-emitting laser (VCSEL) comprising a top surface, wherein the VCSEL is configured to emit a laser beam in a direction perpendicular to the top surface;
a base layer on the top surface of the VCSEL; and
an antireflective diffractive optical element (DOE) on the base layer, wherein the antireflective DOE comprises an array of meta-atom unit cells that each include one or more high index dielectric layers and one or more low index dielectric layers arranged in an identical sequence.

2. The optical system of claim 1, wherein the meta-atom unit cells comprise pillars, posts, or triangle structures arranged in a lattice.

3. The optical system of claim 1, wherein the meta-atom unit cells comprise holes arranged in a lattice.

4. The optical system of claim 1, wherein a wavelength of the laser beam is in a range from 850 to 1480 nanometers.

5. The optical system of claim 4, wherein the one or more high index dielectric layers and the one or more low index dielectric layers have respective thicknesses that are based on the wavelength of the laser beam.

6. The optical system of claim 1, wherein the meta-atom unit cells each include:
a first layer, on the base layer, comprising a first high index dielectric material;
a second layer, on the first layer, comprising a low index dielectric material;
a third layer, on the second layer, comprising a second high index dielectric material; and
a fourth layer, on the third layer, comprising the first high index dielectric material.

7. The optical system of claim 6, wherein the first layer of each meta-atom unit cell has a thickness of approximately 150 nanometers (nm), the second layer of each meta-atom unit cell has a thickness of approximately 330 nm, the third layer of each meta-atom unit cell has a thickness of approximately 100 nm, and the fourth layer of each meta-atom unit cell has a thickness of approximately 150 nm based on a wavelength of the laser beam being 940 nm.

8. The optical system of claim 6, wherein the first high index dielectric material and the second high index dielectric material comprise one or more of amorphous silicon (a-Si), gallium arsenide (GaAs), silicon nitride (SiNx), or titanium dioxide (TiO₂).

9. The optical system of claim 1, wherein the base layer comprises a material that is transparent to a wavelength of the laser beam.

10. The optical system of claim 1, wherein the antireflective DOE has a pitch defined by a periodicity of the meta-atom unit cells.

11. The optical system of claim 10, wherein the pitch does not exceed an upper limit defined by a wavelength of the laser beam divided by an index of the base layer.

12. The optical system of claim 1, wherein the antireflective DOE is configured to one or more of split, shape, or focus the laser beam.

13. A method for fabricating an optical system, comprising:
forming a base layer; and
forming an antireflective diffractive optical element (DOE) comprising an array of meta-atom unit cells on the base layer, wherein the meta-atom unit cells each comprise:
a first set of layers formed from one or more high index dielectric materials, wherein the first set of layers includes a meta-atom layer; and
a second set of layers formed from one or more low index dielectric materials, wherein the first set of layers and the second set of layers are arranged in an identical sequence in each of the meta-atom unit cells.

14. The method of claim 13, wherein the meta-atom unit cells comprise pillars, posts, or triangle structures arranged in a lattice.

15. The method of claim 13, wherein the meta-atom unit cells comprise holes arranged in a lattice.

16. The method of claim 13, wherein the one or more high index dielectric materials comprise one or more of amorphous silicon (a-Si), gallium arsenide (GaAs), silicon nitride (SiNx), or titanium dioxide (TiO₂).

17. A method for operating an optical system, comprising:
emitting, by a vertical-cavity surface-emitting laser (VCSEL) comprising a top surface, a laser beam in a direction perpendicular to the top surface of the VCSEL; and
diffracting the laser beam by an antireflective diffractive coating on the top surface of the VCSEL, wherein the antireflective diffractive coating comprises an array of meta-atom unit cells formed on the top surface of the VCSEL, and wherein the meta-atom unit cells each comprise:
a first set of layers formed from one or more high index dielectric materials, wherein the first set of layers includes a meta-atom layer; and
a second set of layers formed from one or more low index dielectric materials.

18. The method of claim 17, wherein the first set of layers and the second set of layers are arranged in an identical sequence in each of the meta-atom unit cells.

19. The method of claim 17, wherein the meta-atom unit cells are arranged in a lattice.

20. The method of claim 17, wherein the meta-atom layer is amorphous silicon (a-Si).

21. An optical system, comprising:
a substrate; and
a diffractive optical element (DOE) on the substrate, wherein the DOE comprises an array of meta-atom unit cells that each include one or more high index dielectric layers and one or more low index dielectric layers that have respective thicknesses and are arranged in an identical sequence such that the one or more high index dielectric layers and the one or more low index dielectric layers collectively provide the DOE with an antireflective property.

22. The optical system of claim 21, wherein the meta-atom unit cells comprise pillar structures, post structures, triangle structures, or holes arranged in a lattice.

23. The optical system of claim 21, wherein the meta-atom unit cells each include:
a first layer, on the base layer, comprising a first high index dielectric material;
a second layer, on the first layer, comprising a low index dielectric material;
a third layer, on the second layer, comprising a second high index dielectric material; and
a fourth layer, on the third layer, comprising the first high index dielectric material.

24. The optical system of claim 23, wherein the first layer of each meta-atom unit cell has a thickness of approximately 150 nanometers (nm), the second layer of each meta-atom unit cell has a thickness of approximately 330 nm, the third layer of each meta-atom unit cell has a thickness of approximately 100 nm, and the fourth layer of each meta-atom unit cell has a thickness of approximately 150 nm based on a wavelength of the laser beam being 940 nm.

25. The optical system of claim 23, wherein the first high index dielectric material and the second high index dielectric material comprise one or more of amorphous silicon (a-Si), gallium arsenide (GaAs), silicon nitride (SiNx), or titanium dioxide (TiO₂).

26. The optical system of claim 21, wherein the antireflective DOE has a pitch defined by a periodicity of the meta-atom unit cells.

27. The optical system of claim 21, wherein the meta-atom unit cells each include:
a first layer, on the base layer, comprising silicon (Si);
a second layer, on the first layer, comprising silicon dioxide (SiO₂), wherein the first layer and the second layer form a first index-matched pair;
a third layer, on the second layer, comprising Si;
a fourth layer, on the third layer, comprising SiO₂; and
a fifth layer, on the fourth layer, comprising Si, wherein the fourth layer and the fifth layer form a second index-matched pair that is separated from the first index-matched pair by the third layer.
